(19) United States
(12) Patent Application Publication
(10) Pub. No.: US 2026/0255700 A1
(43) Pub. Date: Aug. 27, 2026

(54) IMAGING INTEGRATED CIRCUIT DEVICE AND METHOD OF MAKING SAME

(71) Applicant: Taiwan Semiconductor Manufacturing Company, Ltd., Hsinchu (TW)

(72) Inventors: Zheng-Xun Li, Tainan City (TW); Kai-Chun Hsu, Tainan City (TW); Bo-Ruei Lin, Tainan City (TW)

(21) Appl. No.: 19/060,930

(22) Filed: Feb. 24, 2025

(51) Int. Cl. H10F 39/18; H10F 39/00

(52) U.S. Cl. CPC H10F 39/18; H10F 39/014; H10F 39/8037; H10F 39/809; H10F 39/811; H10F 39/812

(57) ABSTRACT

Some embodiments relate to an integrated circuit (IC) device including a first IC die and a second IC die. The first IC die includes a plurality of pixel circuits. Each of the plurality of pixel circuits includes a photodetector. The second IC die is disposed under, and coupled to, the first IC die and includes a charge storage structure. The charge storage structure includes a lower conductive structure contiguously spanning at least a portion of each of the plurality of pixel circuits in a plan view of the IC device, at least one dielectric structure disposed on the lower conductive structure, and a plurality of upper conductive elements disposed on the at least one dielectric structure. Each of the plurality of upper conductive elements is electrically connected to a corresponding one of the plurality of pixel circuits.

### BACKGROUND

Complementary metal-oxide-semiconductor (CMOS) image sensor (CIS) integrated circuit (IC) devices sometimes incorporate capacitors that may store charge collected in corresponding photosensitive components. Generally, higher capacitance values associated with larger capacitors (e.g., capacitors consuming a relatively large area in a plan view of the device) may provide a larger dynamic range for the associated pixels. However, increased capacitor size may also be associated with a larger pixel area, resulting in reduced image resolution.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of some embodiments of a portion of an integrated circuit (IC) imaging device employing a pixel circuit including a capacitor, according to the present disclosure.

FIGS. 2A and 2B illustrate schematic diagrams of some embodiments of IC imaging devices including a plurality of pixel circuits with corresponding capacitors of a charge storage structure, where the pixel circuits and the capacitors are disposed in different IC dies, according to the present disclosure.

FIGS. 3 and 4 illustrate cross-sectional views of some embodiments of IC imaging devices including a plurality of pixel circuits with corresponding capacitors of a charge storage structure associated with the IC imaging devices of FIGS. 2A and 2B, respectively, according to the present disclosure.

FIGS. 5, 6A, and 6B illustrate cross-sectional views of additional embodiments of IC imaging devices including a plurality of pixel circuits with corresponding capacitors of a charge storage structure, according to the present disclosure.

FIGS. 7A through 7D illustrate plan views of some embodiments of IC imaging devices including a plurality of pixel circuits with corresponding capacitors of a charge storage structure, according to the present disclosure.

FIGS. 8A through 8K illustrate cross-sectional views of some embodiments of an IC imaging device associated with FIG. 3, including a plurality of pixel circuits with corresponding capacitors of a charge storage structure at various stages of manufacture, according to the present disclosure.

FIGS. 9A through 9C illustrate cross-sectional views of some embodiments of an IC imaging device associated with FIG. 4, including a plurality of pixel circuits with corresponding capacitors of a charge storage structure at various stages of manufacture, according to the present disclosure.

FIG. 10 illustrates a methodology of forming an IC die including a charge storage structure with a plurality of capacitors for coupling with another IC die that includes a plurality of pixel circuits for an IC imaging device, in accordance with some embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As indicated above, complementary metal-oxide-semiconductor (CMOS) image sensor (CIS) integrated circuit (IC) devices sometimes incorporate capacitors that may store charge collected in corresponding photosensitive components. For example, each pixel circuit associated with each image pixel may include a capacitor that is configured according to a lateral overflow integration capacitor (LOFIC) arrangement, in which a capacitor may be selectively coupled to a floating diffusion (FD) region by a transistor. Use of such a capacitor for each pixel circuit may facilitate the use of at least two different conversion gains for each pixel, possibly resulting in an increased dynamic range provided by the pixels. Further, as discussed above, higher capacitance values associated with larger capacitors (e.g., capacitors consuming a relatively large area in a plan view of the device) may provide an even larger dynamic range for the associated pixels. However, increased capacitor size may also be associated with a larger pixel area, resulting in reduced image resolution.

As a result, design effort is sometimes directed toward maximizing the capacitor area within the area associated with the corresponding pixel. Factors limiting such an effort may include the space required to route one or more conductive structures (e.g., including a top metal (TM) layer) and associated via (e.g., a top via (TV)), such as for the implementation of a reset circuit (e.g., a RST2 circuit) that pass vertically between each pair of capacitors in the IC device, thus reducing the available area in a plan view of the IC device in which the capacitor may be placed. Also, in some cases, IC design rules specifying a minimum acceptable distance between lower conductive layers (e.g., capacitor bottom metals (CBMs)) of laterally adjacent capacitors may also limit the overall capacitor area that may be implemented.

To address these issues, the present disclosure provides some embodiments of an IC device that includes a first IC die and a second IC die. The first IC die may include a plurality of pixel circuits, where each pixel circuit includes a photodetector. The second IC die may include a charge storage structure that includes a lower conductive structure, at least one dielectric structure disposed on the lower conductive structure, and a plurality of upper conductive structures disposed on the at least one dielectric structure. Each of the upper conductive structures may be electrically connected to a corresponding one of the plurality of pixel circuits. The lower conductive structure may contiguously span at least a portion of each of the plurality of pixel circuits in a plan view of the IC device.

In some embodiments, as described in greater detail below, by employing the lower conductive structure (e.g., serving as a CBM for multiple capacitors), the perimeter of each individual upper conductive element (e.g., serving as a CTM for a corresponding capacitor) may be arranged more closely together under the design rules due to a lack of any associated spacing between individual CBMs. Accordingly, the area of each upper conductive element may be increased, thus possibly increasing the overall capacitance of each capacitor.

Moreover, in some embodiments, the lower conductive structure, by contiguously spanning at least a portion of each of the plurality of pixel circuits, may prevent a significant portion of thermal radiation originating from the second IC die from entering photosensitive portions of the pixel circuits of the first IC die, thus potentially reducing dark-level noise. Other benefits resulting from the various embodiments discussed are also possible.

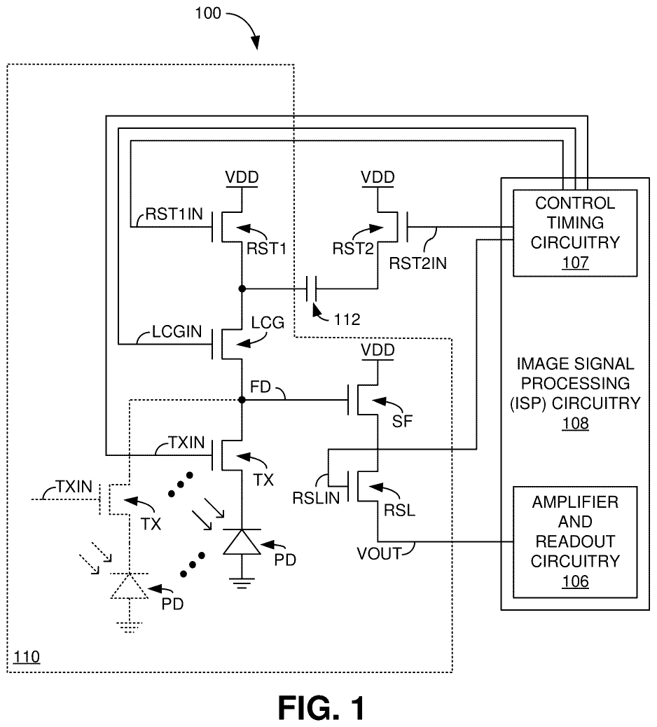

For example, FIG. 1 illustrates a schematic view of some embodiments of a portion of an IC imaging device (or, more simply, an IC device) 100 employing a pixel circuit 110 in conjunction with a capacitor 112 in a LOFIC arrangement, according to the present disclosure. As presented, FIG. 1 depicts a portion of a single pixel of multiple pixels incorporated in IC device 100 to simplify the following discussion.

Pixel circuit 110, as depicted in FIG. 1, may include, for example, a photodetector PD (e.g., a photodiode, such as a PN diode) for a pixel. In some embodiments, photodetector PD includes an anode coupled to a reference voltage (e.g., ground). A transfer transistor TX may include a gate terminal driven by a transfer signal TXIN, a first source-drain connection electrically coupled to a cathode of photodetector PD, and a second source-drain connection electrically coupled to a first source-drain connection of a low conversion gain transistor LCG by way of a floating diffusion region FD. Further, in some embodiments, as described below, more than one photodiode PD and associated transfer transistor TX (e.g., four in a two-by-two configuration) may be employed within a single pixel circuit 110, thus sharing the remainder of the pixel circuit 110 and other circuitry shown in FIG. 1 (e.g.. in a time-division manner).

Further, in some embodiments, in pixel circuit 110, a second source-drain connection of low conversion gain transistor LCG may be coupled to a first terminal of a charge storage capacitor (e.g., capacitor 112). Also, low conversion gain transistor LCG may include a gate terminal driven by a low conversion gain input LCGIN. Accordingly, under the control of LCGIN, low conversion gain transistor LCG may selectively couple capacitor 112 to floating diffusion region FD, thus lowering the conversion gain of pixel circuit 110, as opposed to the high conversion gain associated with floating diffusion region FD alone. In some embodiments, the timing of input signals RST1, LCGIN, and TXIN may be controlled by way of control timing circuitry 107 in image signal processing (ISP) circuitry 108.

The electrical charge collected from photodiode PD via floating diffusion region FD, in some embodiments, may be amplified by a source follower transistor SF, which produces the amplified signal via a first source-drain connection, and whose second source-drain connection is coupled to reference voltage VDD. The amplified signal may be presented to a first source-drain connection of a row selection transistor RSL, as controlled by a row select input RSLIN at a gate connection of row selection transistor RSL, to generate an output voltage VOUT. Output voltage VOUT may then be provided to amplifier and readout circuitry 106 of ISP circuitry 108. In some embodiments, ISP circuitry 108 may also provide additional image processing functionality.

In some embodiments, control timing circuitry 107 may control the internal states of pixel circuit 110 by way of a Reset 1 signal RST1IN and a Reset 2 signal RST2IN to drive the gate terminal of a Reset 1 transistor RST1 and a Reset 2 transistor RST2, respectively. In some embodiments, Reset 1 transistor RST1 may thus selectively connect reference voltage VDD to floating diffusion region FD via low conversion gain transistor LCG to reset floating diffusion region FD. Similarly, Reset 2 transistor RST2 may selectively connect reference voltage VDD to a second terminal of capacitor 112 to reset capacitor 112.

While each pixel circuit 110 may be closely coupled with a corresponding capacitor 112, and possibly an associated Reset 2 transistor RST2, embodiments described herein may separate capacitor 112 and Reset 2 transistor RST2 from pixel circuit 110, such as by locating capacitor 112 and Reset 2 transistor RST2 in a separate IC die, such as a die carrying at least a portion of ISP circuitry 108.

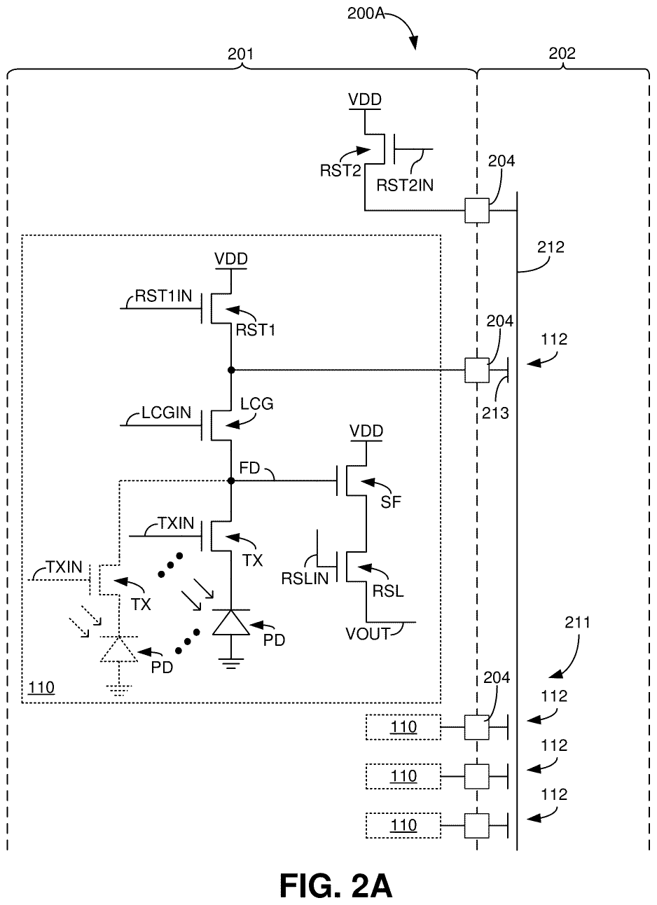

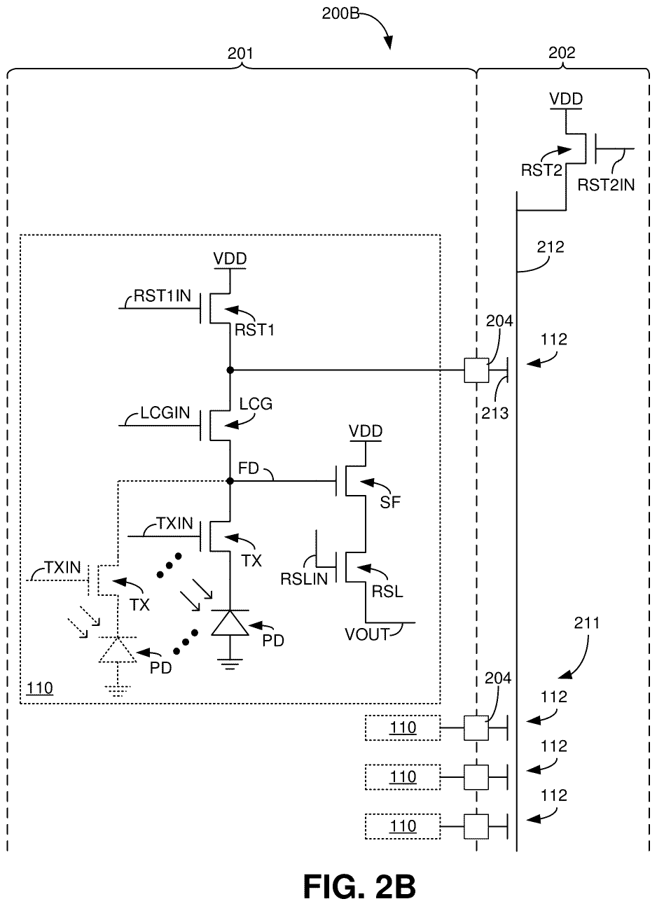

To that end, FIGS. 2A and 2B illustrate schematic diagrams of some embodiments of IC imaging devices 200A and 200B, respectively, including a plurality of pixel circuits 110 with corresponding capacitors 112 of a charge storage structure 211, where pixel circuits 110 and capacitors 112 are disposed in different IC wafers or dies, according to the present disclosure.

For example, in FIG. 2A, four separate pixel circuits 110, each including a corresponding photodetector PD, are included in a first IC die 201 of IC device 200A. While only one pixel circuit 110 is shown in a certain level of detail, remaining pixel circuits 110 may include the same or similar circuitry as that shown for the first pixel circuit 110. In some embodiments, pixel circuits 110 may be arranged in a two-by-two configuration in a plan view of IC device 200A (e.g., including one red pixel, one blue pixel, and two green pixels). However, other numbers and associated arrangements of pixel circuits 110 may be employed in other examples. In some embodiments, first IC die 201 may include many pixel circuits 110 (e.g., hundreds, thousands, or millions of pixel circuits 110) in various arrangements.

Also as depicted in FIG. 2A, each pixel circuit 110 of first IC die 201 may be electrically connected with a corresponding capacitor 112 located in a second IC die 202. Additionally, in some embodiments, conductive elements on one side of capacitors 112 may be provided as a single (e.g., lower) conductive structure 212 that may be shared among capacitors 112 (e.g., as a CBM structure). Simultaneously, each capacitor 112 may include a second separate (e.g., upper) conductive element 213 (e.g., as a CTM structure) that is connected to a corresponding pixel circuit 110. In some embodiments, each separate conductive structure may be connected to a corresponding pixel circuit 110 via a conductive bonding structure 204 employed to couple first IC die 201 to second IC die 202. Thus, by sharing a single conductive structure 212, capacitors 112 may jointly form a combined charge storage structure 211.

In addition to capacitors 112, ISP circuitry 108 may be included in second IC die 202, but is not explicitly illustrated in FIGS. 2A and 2B to simplify the associated discussion.

Instead of employing a separate Reset 2 transistor RST2 to reset each corresponding capacitor 112, FIG. 2A depicts embodiments in which a single Reset 2 transistor RST2, controlled by Reset 2 signal RST2IN, may be connected to a terminal (e.g. single conductive structure 212) of each capacitor 112. In some embodiments, one Reset 2 transistor RST2 may be included for each plurality of capacitors 112 (e.g., capacitors 112 for a two-by-two set of pixel circuits 110, an entire row of pixel circuits 110, or the like). More specifically, as indicated in FIG. 2A, a source-drain connection of Reset 2 transistor RST2 may reside in first IC die 201 and be coupled to single conductive structure 212 by way of a conductive bonding structure 204.

In FIG. 2B, an IC device 200B may include pixel circuits 110 in first IC die 201 and associated capacitors 112 in second IC die 202, as discussed above in conjunction with FIG. 2A. However, in the embodiments of FIG. 2B, a single Reset 2 transistor RST2, while being coupled with single conductive structure 212, is located in second IC die 202 instead of first IC die 201.

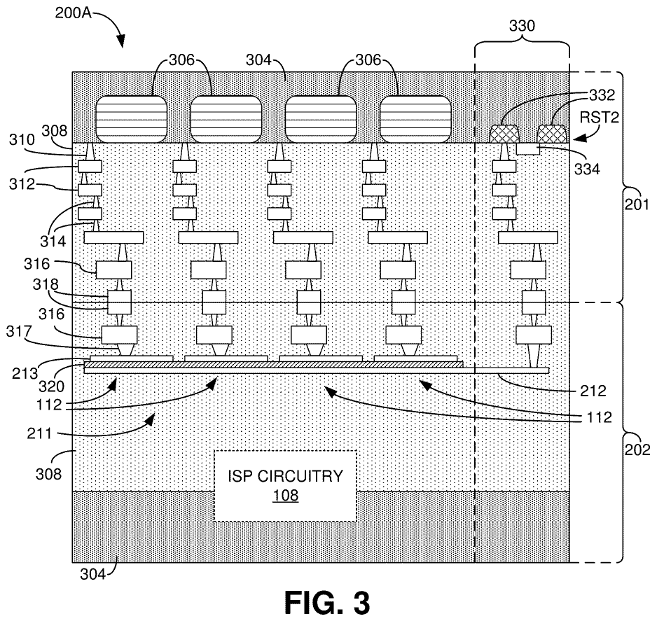

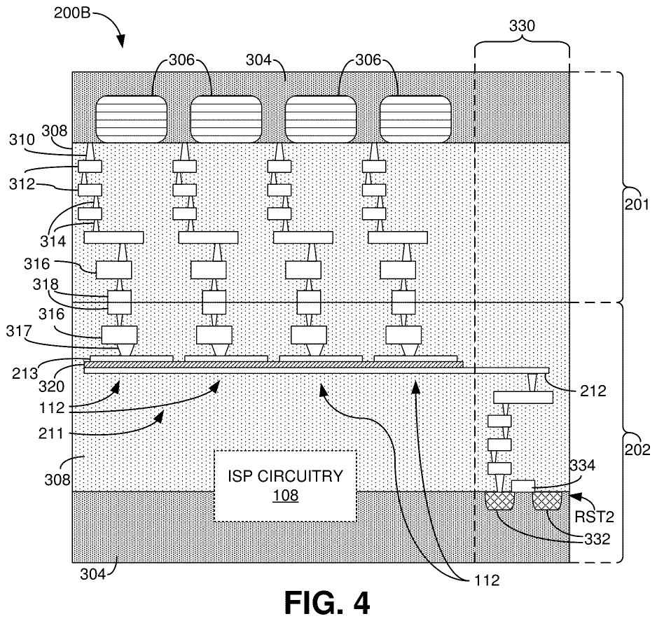

FIGS. 3 and 4 illustrate cross-sectional views of some embodiments of IC imaging devices 200A and 200B, respectively, including a plurality of pixel circuits with corresponding capacitors 112 of a charge storage structure 211 associated with the IC imaging devices 200A and 200B of FIGS. 2A and 2B, respectively, according to the present disclosure.

More specifically, regarding both FIGS. 3 and 4, first IC die 201 may include a substrate 304 (e.g., a semiconductor substrate, such as silicon) that includes a photosensitive region 306 to serve as a photodetector (e.g., PN photodiode or “pinned” photodiode) in conjunction with the surrounding area of substrate 304. In some embodiments, substrate 304 may be p-doped silicon, and photosensitive region 306 may be doped with ions to create n-doped regions. In some embodiments, each photodetector denoted by photosensitive region 306 may be a portion of a pixel circuit 110, as shown in FIG. 2A. However, the remainder of such pixel circuit is not depicted in FIG. 3 or 4, or any subsequent figures, to focus and simplify the following discussion.

One or more dielectric layers or structures 308, within which multiple conductive structures are located, may be disposed over substrate 304. More specifically, as shown in FIG. 3, a set of conductive structures may couple each pixel circuit with a corresponding capacitor 112 of charge storage structure 211. Further, each conductive structure may include a conductive contact 310, one or more conductive layers 312, and intervening conductive vias 314. Also, in some embodiments, a top conductive layer 316 may be coupled by way of a conductive via 314 to a conductive bonding structure 318 at a side of dielectric layer 308. Dielectric layers 308 may include one or more dielectric materials, including, but not limited to, silicon oxide (SiOx) (e.g., silicon oxide (SiO2)), silicon nitride (SiN), silicon carbide (SiC), carbon-doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like. The conductive structures may include copper (Cu) or another metal, metal alloy, or other conductive material.

Second IC die 202 of FIG. 3 may include a substrate 304 and one or more dielectric layers or structures 308, each of which may include the same or similar types of materials as those listed above in connection with first IC die 201. Further, ISP circuitry 108, or portions thereof, may be implemented within substrate 304 and dielectric layers 308. Further, charge storage structure 211 may be located within dielectric layers 308. Moreover, one or more conductive structures (e.g., top conductive structure 316, conductive vias 317, and conductive bonding structures 318) may couple each upper conductive element 213 to a corresponding conductive structure of first IC die 201 to connect each capacitor 112 of charge storage structure 211 to a corresponding pixel circuit of first IC die 201.

More specifically, in some embodiments, charge storage structure 211 may include a lower conductive structure 212, a dielectric element 320, and a plurality of upper conductive elements 213 (e.g., one each for a corresponding capacitor 112 of FIG. 2A). Consequently, in some embodiments, each capacitor 112 may take the form of a metal-insulator-metal (MIM) capacitor. In some embodiments, lower conductive structure 212 and the plurality of upper conductive elements 213 may include titanium nitride (TiN), an aluminum-copper (AlCu) alloy, tungsten (W), and/or another metal or metal alloy, polycrystalline silicon (poly-Si), and/or another conductive material. Further, in some embodiments, dielectric element 320 may include a high-κ dielectric material, such as hafnium silicate (HfO₆Si₂), zirconium silicate (ZrSiO₄), hafnium dioxide (HfO₂), zirconium dioxide (ZrO₂), and/or the like. In other embodiments, dielectric element 320 may include other dielectric materials that are not high-κ dielectric or insulating materials.

As depicted in FIGS. 3 and 4, the perimeters (e.g., lateral edges) of adjacent upper conductive elements 213 may be placed close to each other, due at least in part to the use of a single lower conductive structure 212. Otherwise, the use of multiple lower conductive structures 212 (e.g., one per each corresponding upper conductive element 213), necessitating some lateral separation therebetween, may cause a lateral spacing between upper conductive elements 213 that may be greater than that depicted in FIG. 3. Consequently, the capacitance provided by each capacitor 112 associated with each upper conductive element 213 shown in FIGS. 3 and 4 may be greater than otherwise expected. Additionally, in some embodiments, lower conductive structure 212 may extend laterally across a significant portion of second IC die 202 in a contiguous manner, thus possibly shielding thermal radiation generated by ISP circuitry 108 from photosensitive regions 306 associated with the pixel circuits described above with respect to FIGS. 2A and 2B. Such a reduction in thermal radiation may reduce the amount of dark noise being induced into photosensitive regions 306.

In some embodiments, the plurality of pixel circuits coupled with charge storage structure 211 may include any number of two or more pixel circuits in any arrangement thereof in the plan view of IC device 200A. For example, the plurality of pixel circuits may be arranged as a two-by-two pixel group in the plan view of IC device 200A, as indicated above. In other examples, pixel circuits associated with a particular row of pixel circuits may be coupled to a single charge storage structure 211.

As particularly illustrated in FIG. 3, a Reset 2 transistor RST2 (e.g., as discussed above with respect to FIG. 2A) may be electrically connected by way of conductive structures (e.g., including top conductive structure 316, conductive vias 317, and conductive bonding structures 318 in both first IC die 201 and second IC die 202) to single lower conductive structure 212. In some embodiments, Reset 2 transistor RST2 may be a transistor structure that includes a conductive gate structure 334 in dielectric layers 308 and a pair of source-drain regions 332 in substrate 304 of first IC die 201. As discussed above, Reset 2 transistor RST2 may be used to reset capacitors 112 of charge storage structure 211.

In some embodiments, as depicted in FIG. 3, Reset 2 transistor RST2 and the associated conductive structures may be located in a peripheral area or region 330 of first IC die 201 and second IC die 202 lateral to capacitors 112 of charge storage structure 211, and the photosensitive regions 306 associated with the pixel circuits of first IC die 201. In some embodiments, the greater the number of pixel circuits coupled to charge storage structure 211, the less the relative amount of area of IC device 200A in the plan view is reserved for peripheral area 330.

In FIG. 4, an IC device 200B includes first IC die 201 and second IC die 202 with many of the same structures (e.g., substrate 304, dielectric layers or structures 308, photosensitive regions 306 of a plurality of pixel circuits, charge storage structure 211, and the plurality of conductive structures coupling charge storage structure 211 to the plurality of pixel circuits) as described above in association of IC device 200A of FIG. 3, and thus possesses the same or similar characteristics of IC device 200A. In some embodiments, IC device 200B is distinguished from IC device 200A by Reset 2 transistor RST2 being disposed in second IC die 202 instead of first IC die 201. More specifically, Reset 2 transistor RST2 may be disposed within peripheral area 330 of second IC die 202, including conductive gate structure 334 in dielectric layers 308 and a pair of source-drain regions 332 in substrate 304 of second IC die 202. Consequently, in IC device 200B, Reset 2 transistor RST2 may be coupled with a lower side of single conductive structure 212 instead of an upper side of single conductive structure 212, as shown in IC device 200A of FIG. 3.

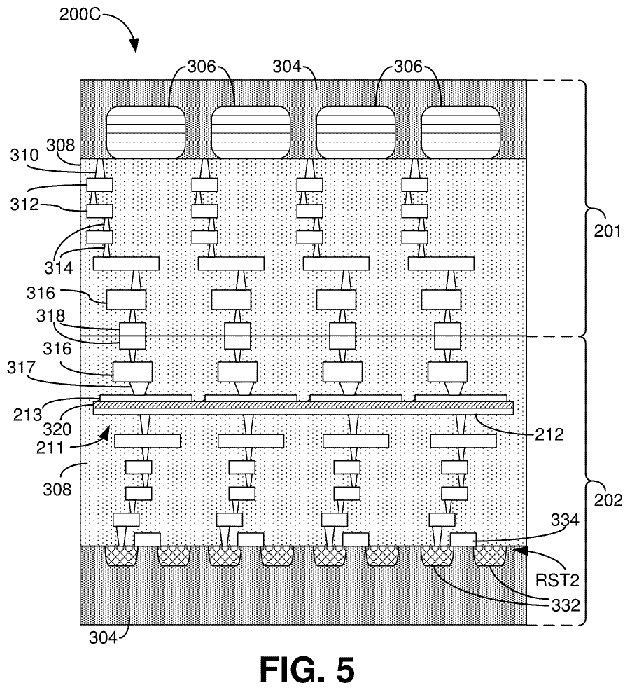

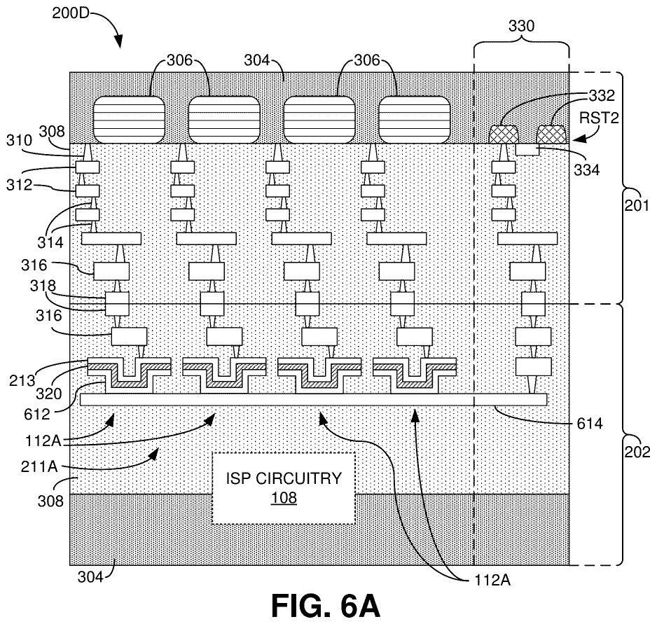

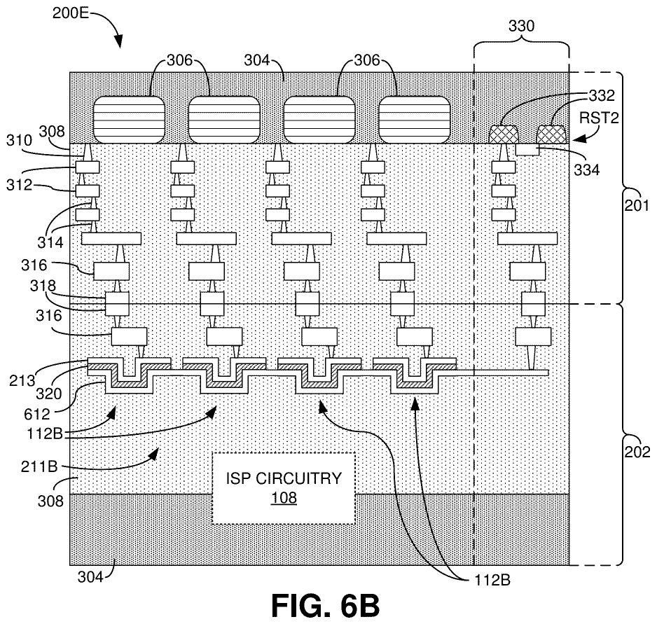

FIGS. 5, 6A, and 6B illustrate cross-sectional views of additional embodiments of IC imaging devices including a plurality of pixel circuits with corresponding capacitors 112 of charge storage structure 211, according to the present disclosure. In FIG. 5, in some embodiments, one or more Reset 2 transistors RST2 may be disposed in second IC die 202 of an IC device 200C and coupled with single conductive structure 212 of charge storage structure 211, thus allowing each Reset 2 transistor RST2 to be operated on a pixel-specific basis (e.g., to reset the charge stored on the capacitor of charge storage structure 211 of the associated pixel circuit). In yet other embodiments, a number of Reset 2 transistors RST2 less than one per upper conductive element 213 (e.g., one per charge storage structure 211) may be employed in second IC die 202. Consequently, in such embodiments, IC device 200C does not necessarily include a peripheral area or region lateral to charge storage structure 211 to provide specific volume in IC device 200C that is reserved for one or more Reset 2 transistors RST2.

FIG. 6A illustrates an IC device 200D that is the same or similar to IC device 200A of FIG. 3, with the exception of a charge storage structure 211A in which each capacitor 112A associated therewith may be arranged as a three-dimensional metal-insulator-metal (3D-MIM) capacitor in which one or more the layers of each capacitor 112A include one or more trenches, thus increasing the possible capacitor value of each capacitor 112A. As depicted in FIG. 6A, charge storage structure 211A may include a plurality of capacitors 112A (e.g., one per pixel circuit), where each capacitor 112A includes a separate lower conductive element 612, dielectric element 320, and upper conductive element 213. In some embodiments, the plurality of lower conductive elements 612 may be coupled to a conductive structure 614 (e.g., a metal or conductive layer) to which a Reset 2 transistor RST2 may be connected (e.g., in a peripheral area 330 in second IC die 202). Alternatively, as shown in IC device 200E of FIG. 6B, a single lower conductive element 612A may span across all capacitors 112B to form a charge storage capacitor structure 211B. In such embodiments, single lower conductive element 612A may extend into peripheral area 330 to be electrically connected with Reset 2 transistor RST2. In yet other embodiments, other capacitor arrangements that include a single lower conductive element or structure may be employed.

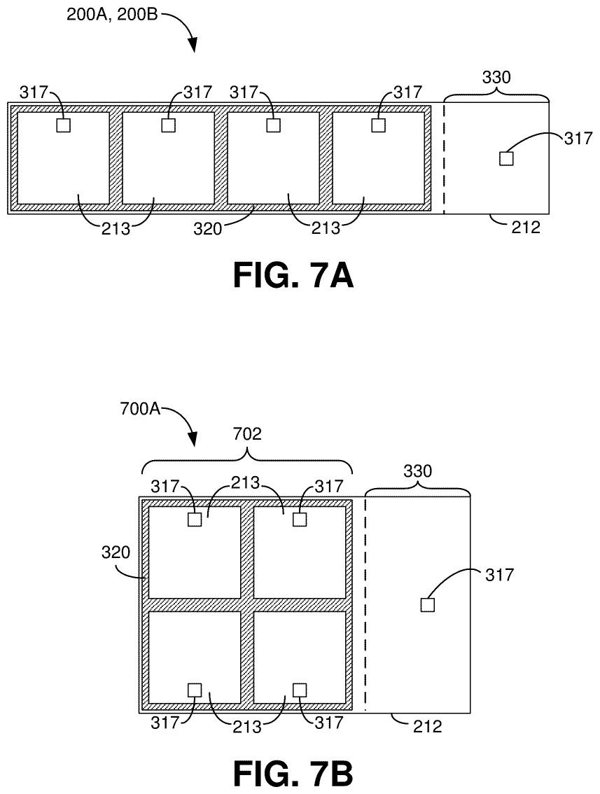

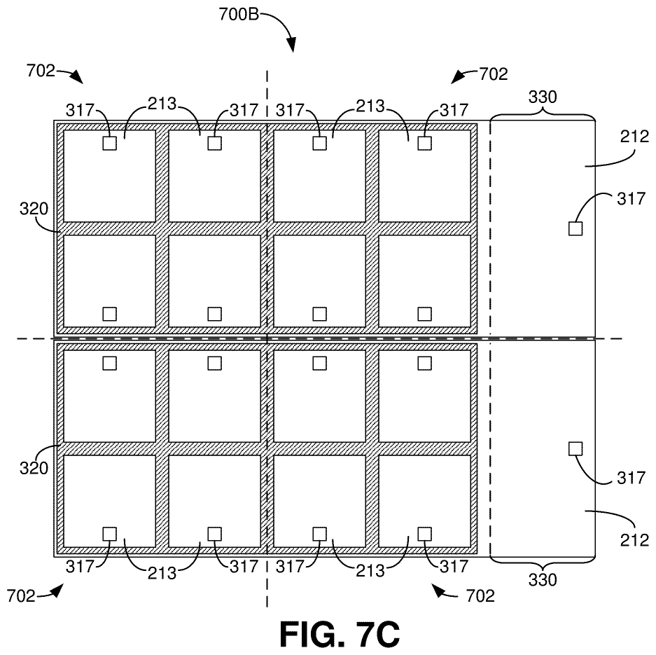

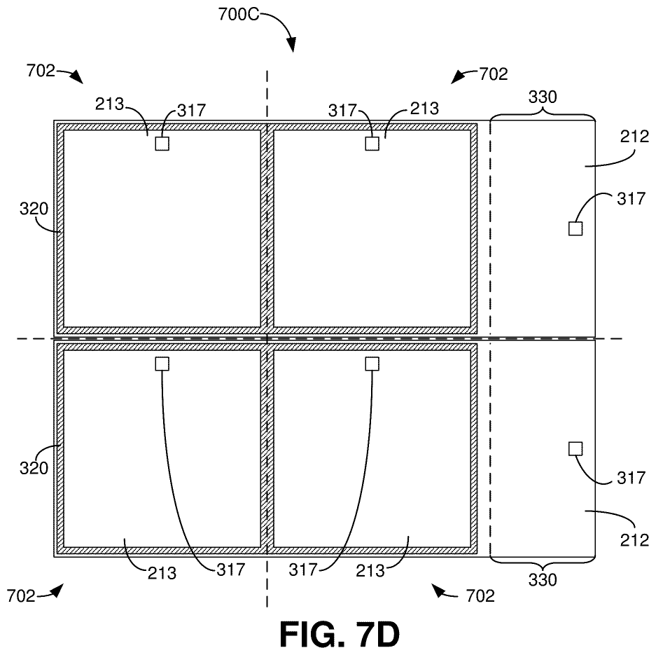

FIGS. 7A through 7D illustrate plan views of some embodiments of IC imaging devices including a plurality of pixel circuits with corresponding capacitors of a charge storage structure, according to the present disclosure. For example, FIG. 7A illustrates a plan view of IC device 200A of FIG. 3 and IC device 200B of FIG. 4, which depicts single lower conductive structure 212 (e.g., which extends into peripheral area 330 and is connected to a Reset 2 transistor RST2, not shown in FIG. 7A), dielectric element 320 disposed over single lower conductive structure 212, and the plurality of upper conductive elements 213 (e.g., arranged laterally along a line). Also depicted in FIG. 7A are conductive vias 317 in contact with upper conductive elements 213 and lower conductive structure 212 of IC devices 200A and 200B. As shown, a lateral separation distance between adjacent upper conductive elements 213 is relatively limited due to the presence of single lower conductive structure 212.

FIG. 7B illustrates a plan view of an IC device 700A in which the pixel circuits, as well as the associated upper conductive elements 213, are arranged in an array (e.g., a two-by-two pixel group 702). In such embodiments, each pixel group 702 may include pixels sensitive to different wavelength bands of light (e.g., one red pixel, one blue pixel, and two green pixels). Such pixels of pixel group 702 are thus electrically coupled to the same lower conductive structure 212 and associated Reset 2 transistor RST2 not explicitly depicted in FIG. 7B. Further, in FIG. 7C, an IC device 700B may include four such pixel groups 702 (and in other embodiments, five or more pixel groups 702), where each row of pixel groups 702 of IC device 700B may be coupled to the same lower conductive structure 212. In cases in which more pixels or pixel groups are coupled to the same lower conductive structure 212, relatively less area of lower conductive structure 212 in the plan view may be devoted, on a per-pixel basis, to peripheral area 330.

In both FIGS. 7B and 7C, each pixel group 702 may include a single photodetector (e.g., photodetector PD of FIG. 1) in each of four pixel circuits (e.g., pixel circuit 110 of FIG. 1). In contrast, in FIG. 7D, each pixel group 702 of an IC device 700C may include four photodetectors within a single pixel circuit, thus allowing each pixel group 702 to be coupled with a single upper conductive element 213.

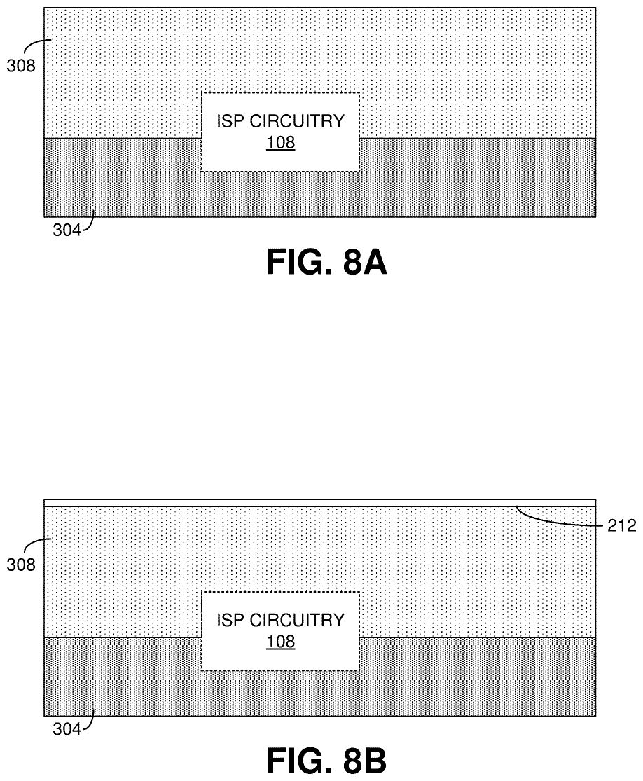

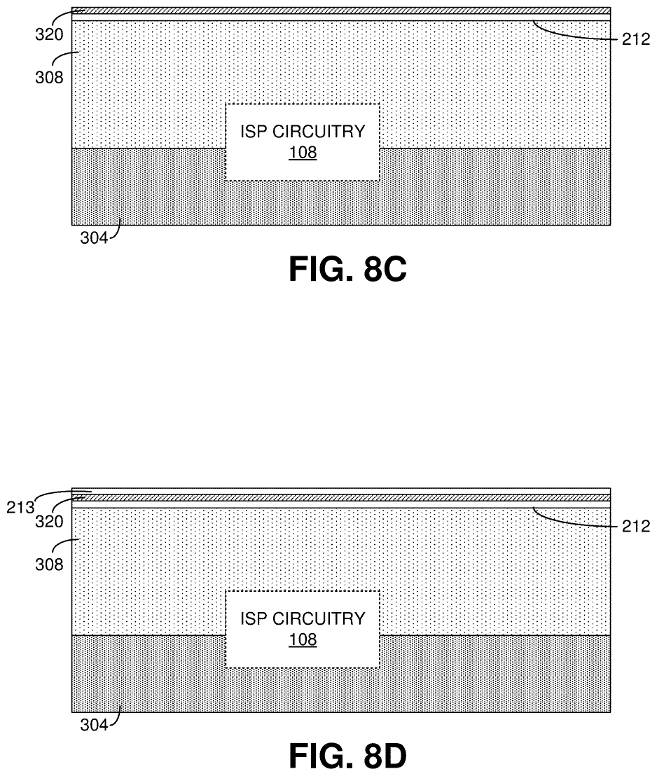

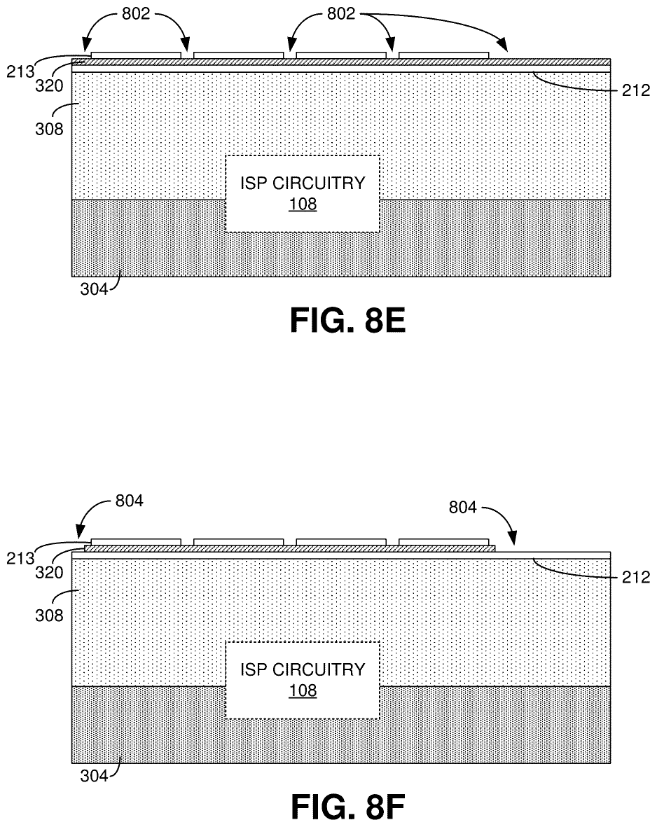

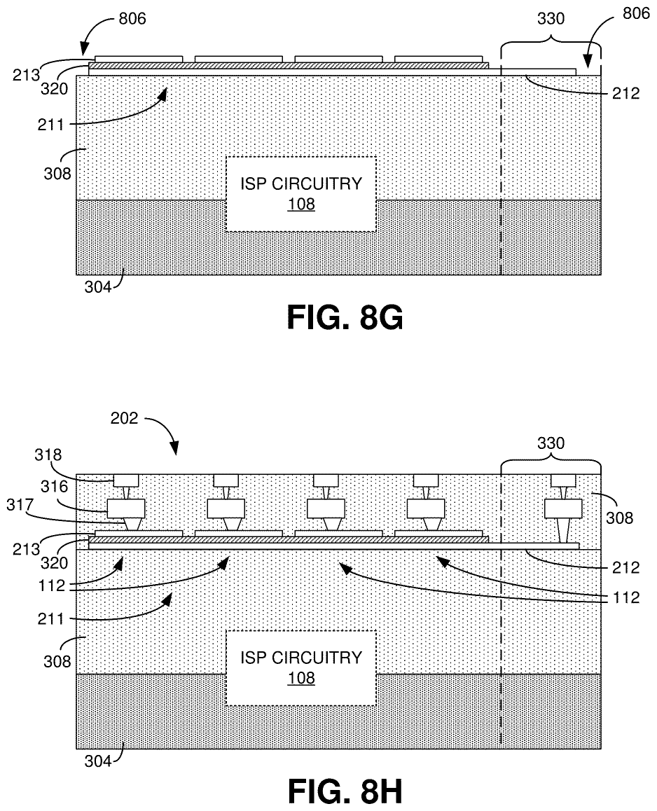

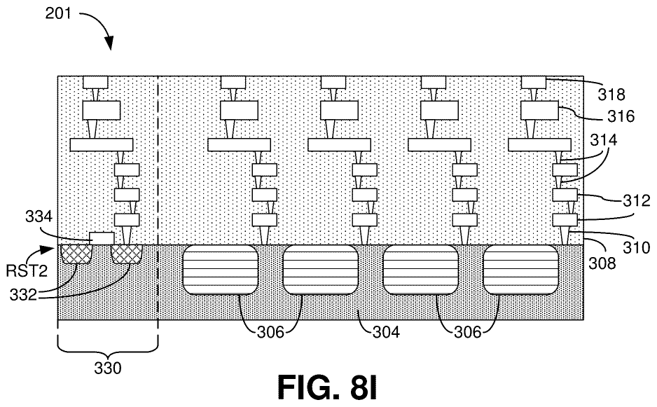

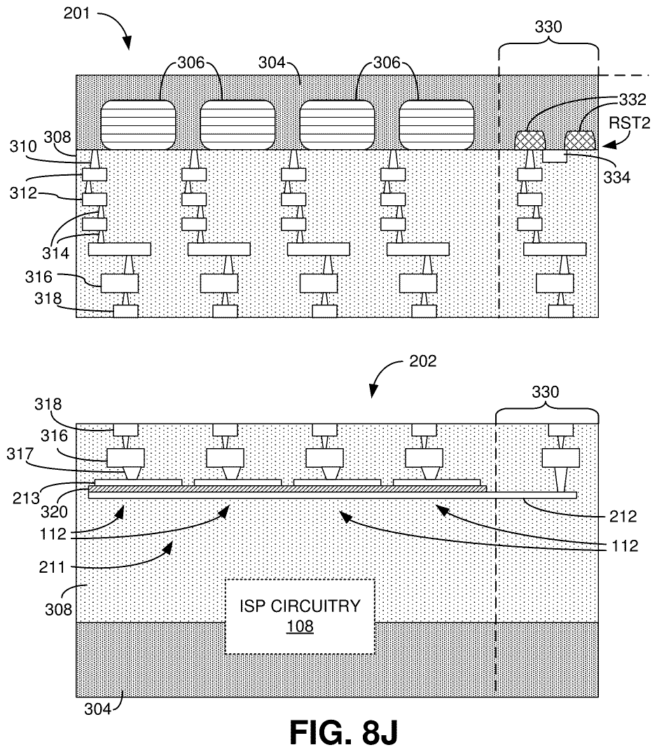

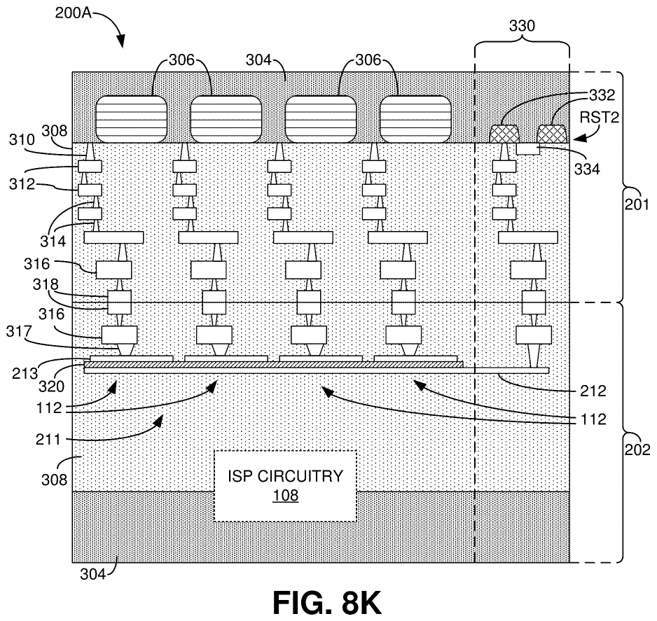

FIGS. 8A through 8K illustrate cross-sectional views of some embodiments of an IC imaging device 200A associated with FIG. 3 including a plurality of pixel circuits with corresponding capacitors 112 of a charge storage structure 211 at various stages of manufacture, according to the present disclosure. Although FIGS. 8A through 8K are described as a series of acts, it will be appreciated that these acts are not limiting in that the order of the acts within each series can be altered in other embodiments, and the methods disclosed are also applicable to other structures. In other embodiments, some acts that are illustrated and/or described may be omitted in whole or in part. In particular, the acts described below are primarily directed to the forming of charge storage structure 211 to simplify the following discussion.

For example, FIG. 8A illustrates dielectric layers or structures 308 disposed over substrate 304. Further, fabricated therein may be ISP circuitry 108, as discussed above. In some embodiments, substrate 304 may include a semiconductor material (e.g., silicon (Si)). Dielectric layers 308 may include one or more dielectric materials, including, but not limited to, silicon oxide (SiOx) (e.g., silicon oxide (SiO2)), silicon nitride (SiN), silicon carbide (SiC), carbon-doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like.

FIG. 8B illustrates the forming (e.g., deposition) of a first layer of conductive material (e.g., titanium nitride (TiN), an aluminum-copper (AlCu) alloy, tungsten (W), and/or another metal or metal alloy, polycrystalline silicon (poly-Si), and/or another conductive material) for lower conductive structure 212.

FIG. 8C illustrates the forming (e.g., deposition) of a layer of dielectric material for dielectric element 320 over lower conductive structure 212. In some embodiments, the dielectric material may include a high-κ dielectric material, such as hafnium silicate (HfO₆Si₂), zirconium silicate (ZrSiO₄), hafnium dioxide (HfO₂), zirconium dioxide (ZrO₂), and/or the like. In other embodiments, the layer of dielectric material may include other dielectric materials that are not high-κ dielectric or insulating materials.

FIG. 8D illustrates the forming (e.g., deposition) a second layer of conductive material for upper conductive elements 213. The second layer of conductive material may include the same or different material employed in the first layer of conductive material.

FIG. 8E illustrates the removal (e.g., by photolithography and etching) of portions 802 of the second layer of conductive material to form upper conductive elements 213.

FIG. 8F illustrates the removal (e.g., by photolithography and etching) of portions 804 of the layer of dielectric material to form dielectric element 320. Similarly, FIG. 8G illustrates the removal (e.g., by photolithography and etching) of portions 806 of the first layer of conductive material to form single lower conductive structure 212, which may extend into a peripheral area or region 330 laterally external to upper conductive elements 213. In some embodiments, at least some portions of the layer of dielectric material and the first layer of conductive material may be removed in a single etching operation.

FIG. 8H illustrates the forming (e.g., by a combination of deposition, photolithography, and etching) of second dielectric layer 308, top conductive layers 316, conductive vias 317, and conductive bonding structures 318 to form a set of conductive structures, where each conductive structure is formed on a corresponding upper conductive element 213 and extends to an upper side of second IC die 202. Further, an additional conductive structure may be formed that extends from lower conductive structure 212 to the upper side of second IC die 202 within peripheral area or region 330.

FIG. 8I illustrates first IC die 201 of FIG. 3 after fabrication. In some embodiments, semiconductor substrate 304 may be doped to form photosensitive regions 306, source-drain regions 332 for Reset 2 transistor RST2, and other doped regions not explicitly shown therein. Various dielectric layers 308, along with included conductive contacts 310, conductive layers 312, top conductive layer 316, intervening conductive vias 314, and conductive bond structures 318, may then be formed over substrate 304. As a result, a plurality of conductive structures may be formed, each of which may couple a pixel circuit associated with one of the photosensitive regions 306 to an opposing (e.g., upper) side of dielectric layers 308. An additional conductive structure may couple a source-drain region 332 of Reset 2 transistor RST2 with the opposing side of dielectric layers 308.

FIG. 8J illustrates the rotation or flipping of completed first IC die 201 to orient first IC die 201 appropriately relative to second IC die 202 so that conductive bonding structures 318 of first IC die 201 are aligned with conductive bonding structures 318 of second IC die 202. In some embodiments, conductive bonding structures 318 may include copper (Cu) or another metal or metal alloy, or another conductive material.

FIG. 8K illustrates the bonding (e.g., by way of thermal or heat-based bonding) of the upper side of first IC die 201 with the upper side of second IC die 202. In some embodiments, this bonding may be performed by placing the upper surfaces of first IC die 201 and second IC die 202 (e.g., at room temperature) together to bond upmost dielectric layers 308, and then heating the resulting assembly to cause each of conductive bonding structures 318 of first IC die 201 to contact a corresponding one of conductive bonding structures 318 of second IC die 202.

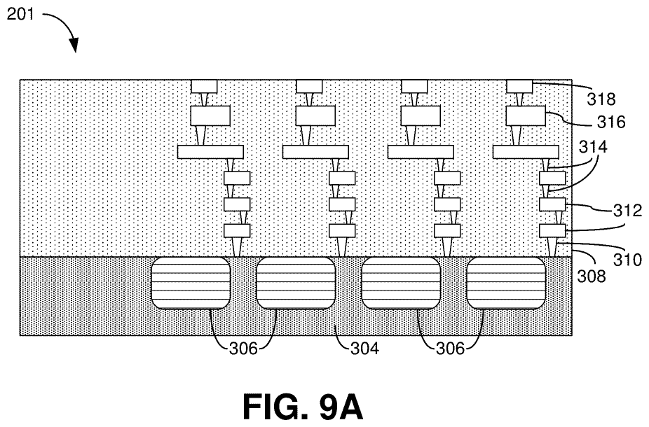

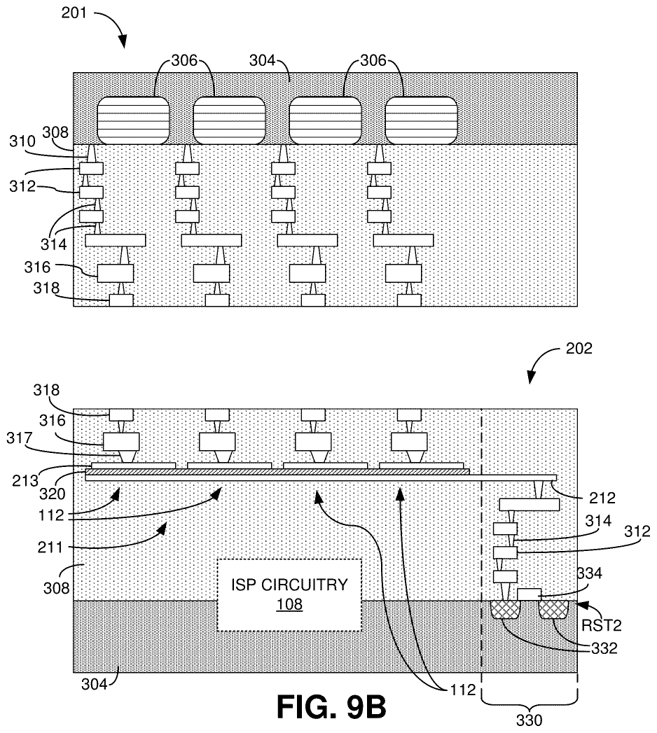

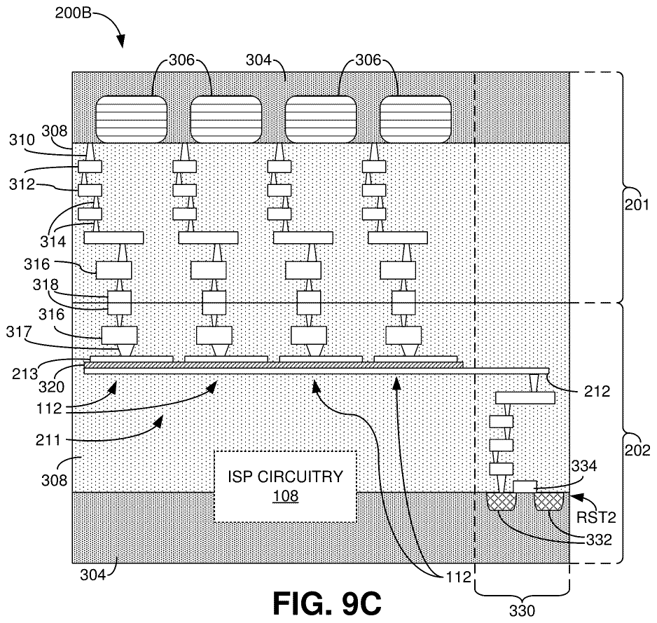

FIGS. 9A through 9C illustrate cross-sectional views of some embodiments of an IC imaging device 200B associated with FIG. 4, including a plurality of pixel circuits with corresponding capacitors 112 of a charge storage structure 211 at various stages of manufacture, according to the present disclosure. FIG. 9A, for example, illustrates a completed first IC die 201, as described earlier in conjunction with IC device 200B of FIG. 4.

FIG. 9B illustrates the rotation or flipping of completed first IC die 201 of FIG. 9A to orient first IC die 201 appropriately relative to second IC die 202 so that conductive bonding structures 318 of first IC die 201 at an upper side thereof are aligned with conductive bonding structures 318 at an upper side of second IC die 202. Additionally, in some embodiments, second IC die 202 is formed in a manner similar to that described above in connection with FIGS. 8A through 8H, with the addition of Reset 2 transistor RST2, including doped source-drain regions 332 in substrate 304 and gate structure 334 in dielectric layers 308, as well as a conductive structure (e.g., including conductive layers 312 and conductive vias 314) connecting one source-drain region 332 of Reset 2 transistor RST2 to lower conductive structure 212. Accordingly, second IC die 202 is as described above with respect to second IC die 202 of FIG. 4.

FIG. 9C illustrates the bonding (e.g., using thermal or heat-based bonding) of the upper side of first IC die 201 with the upper side of second IC die 202. In some embodiments, this bonding may be performed by placing the upper surfaces of first IC die 201 and second IC die 202 (e.g., at room temperature) together to bond third dielectric layers 308, and then heating the resulting assembly to cause each of conductive bonding structures 318 of first IC die 201 to contact a corresponding one of conductive bonding structures 318 of second IC die 202.

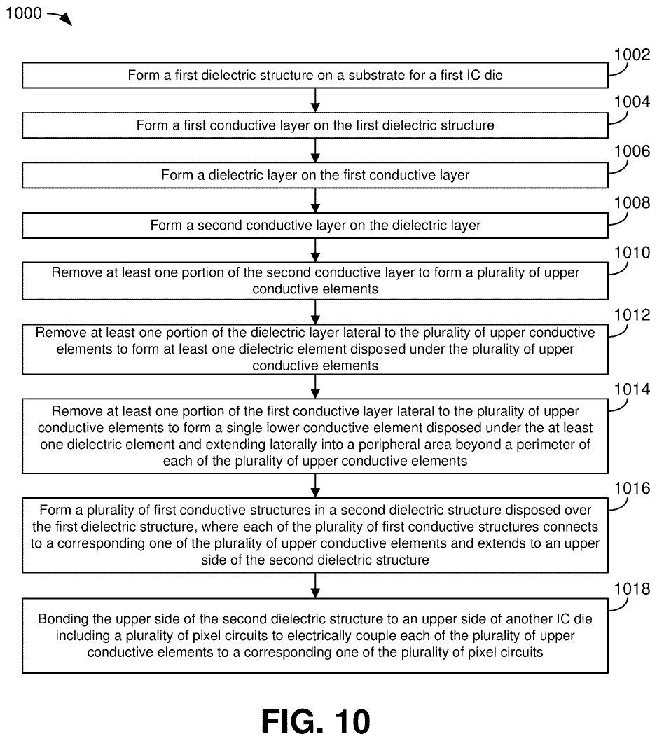

FIG. 10 illustrates a methodology 1000 of forming an IC die (e.g., second IC die 202 of FIG. 3) including a charge storage structure (e.g., charge storage structure 211 of FIG. 3) with a plurality of capacitors (e.g., capacitors 112 of FIG. 3) for coupling with another IC die (e.g. first IC die 201 of FIG. 3) that includes a plurality of pixel circuits for an IC imaging device (e.g., IC imaging device 200A of FIG. 3), in accordance with some embodiments of the present disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At Act 1002, for example, a first dielectric structure (e.g., dielectric structure 308 of FIG. 8A) is formed on a substrate (e.g., substrate 304 of FIG. 8A) for an IC die (e.g., second IC die 202 of FIGS. 8J and 9B). FIG. 8A illustrates a cross-sectional view of some embodiments corresponding to Act 1002.

At Act 1004, a first conductive layer is formed on the first dielectric structure. FIG. 8B illustrates a cross-sectional view of some embodiments corresponding to Act 1004.

At Act 1006, a dielectric layer is formed over the first conductive layer. FIG. 8C illustrates a cross-sectional view of some embodiments corresponding to Act 1006.

At Act 1008, a second conductive layer is formed on the dielectric layer. FIG. 8D illustrates a cross-sectional view of some embodiments corresponding to Act 1008.

At Act 1010, at least one portion of the second conductive layer is removed to form a plurality of upper conductive elements (e.g., upper conductive elements 213 of FIG. 8E). FIG. 8E illustrates a cross-sectional view of some embodiments corresponding to Act 1010.

At Act 1012, at least one portion of the dielectric layer lateral to the plurality of upper conductive elements is removed to form at least one dielectric element (e.g., dielectric element 320 of FIG. 8F) disposed under the plurality of upper conductive elements. FIG. 8F illustrates a cross-sectional view of some embodiments corresponding to Act 1012.

At Act 1014, at least one portion of the first conductive layer lateral to the plurality of upper conductive elements is removed to form a single lower conductive element (e.g., lower conductive structure 212 of FIG. 8G) disposed under the at least one dielectric element and extending laterally into a peripheral area (e.g., peripheral area 330 of FIG. 8G) beyond a perimeter of each of the plurality of upper conductive elements. FIG. 8G illustrates a cross-sectional view of some embodiments corresponding to Act 1014.

At Act 1016, a plurality of first conductive structures is formed in a second dielectric structure (e.g., second dielectric structure 308 of FIG. 8H) disposed over first dielectric structure 308, where each of the plurality of first conductive structures connects to a corresponding one of the plurality of upper conductive elements and extends to an upper side of the second dielectric structure. FIG. 8H illustrates a cross-sectional view of some embodiments corresponding to Act 1016.

At Act 1018, the upper side of the second dielectric structure is bonded to an upper side of another IC die (e.g., first IC die 201 of FIGS. 8J and 9B) including a plurality of pixel circuits (e.g., pixel circuits 110 of FIGS. 2A and 2B) to electrically couple each of the plurality of upper conductive elements to a corresponding one of the plurality of pixel circuits. FIGS. 8K and 9C illustrate cross-sectional views of some embodiments corresponding to Act 1018.

Some embodiments relate to an IC device. The IC device includes a first IC die and a second IC die. The first IC die includes a plurality of pixel circuits. Each of the plurality of pixel circuits includes a photodetector. The second IC die is disposed under, and coupled to, the first IC die and includes a charge storage structure. The charge storage structure includes a lower conductive structure contiguously spanning at least a portion of each of the plurality of pixel circuits in a plan view of the IC device, at least one dielectric structure disposed on the lower conductive structure, and a plurality of upper conductive elements disposed on the at least one dielectric structure. Each of the plurality of upper conductive elements is electrically connected to a corresponding one of the plurality of pixel circuits. The IC device further includes at least one transistor structure including a source-drain region connected to the lower conductive structure. The at least one transistor structure is disposed in one of the first IC die or the second IC die.

Some embodiments relate to another IC device. The IC device includes a first IC die and a second IC die. The first IC die includes a plurality of pixel circuits. Each of the plurality of pixel circuits includes a photodetector. The second IC die is disposed under, and coupled to the first IC die, and includes a charge storage structure. The charge storage structure contiguously spans at least a portion of each of the plurality of pixel circuits in a plan view of the IC device. The charge storage device includes a plurality of capacitor structures. Each of the plurality of capacitor structures is disposed under and coupled to a corresponding one of the plurality of pixel circuits. The plurality of capacitor structures includes a single lower conductive structure contiguously spanning at least a portion of each of the plurality of capacitor structures in the plan view of the IC device.

Some embodiments relate to a method. The method includes: forming a first dielectric structure on a substrate for an IC die; forming a first conductive layer on the first dielectric structure; forming a dielectric layer on the first conductive layer; forming a second conductive layer on the dielectric layer; removing at least one portion of the second conductive layer to form a plurality of upper conductive elements; removing at least one portion of the dielectric layer lateral to the plurality of upper conductive elements to form at least one dielectric element disposed under the plurality of upper conductive elements; removing at least one portion of the first conductive layer lateral to the plurality of upper conductive elements to form a single lower conductive element disposed under the at least one dielectric element and extending laterally into a peripheral area beyond a perimeter of each of the plurality of upper conductive elements; forming a plurality of first conductive structures in a second dielectric structure disposed over the first dielectric structure, wherein each of the plurality of first conductive structures connects to a corresponding one of the plurality of upper conductive elements and extends to an upper side of the second dielectric structure; and bonding an upper side of the second dielectric structure to an upper side of the another IC die including a plurality of pixel circuits to electrically couple each of the plurality of upper conductive elements to a corresponding one of the plurality of pixel circuits.

It will be appreciated that in this written description, as well as in the claims below, the terms “first”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a first IC die comprising a plurality of pixel circuits, each of the plurality of pixel circuits comprising a photodetector; and
a second IC die disposed under, and coupled to, the first IC die, the second IC die comprising a charge storage structure, the charge storage structure comprising:
a lower conductive structure contiguously spanning at least a portion of each of the plurality of pixel circuits in a plan view of the IC device;
at least one dielectric structure disposed on the lower conductive structure; and
a plurality of upper conductive elements disposed on the at least one dielectric structure, each of the plurality of upper conductive elements electrically connected to a corresponding one of the plurality of pixel circuits;
wherein the IC device further includes at least one transistor structure comprising a source-drain region connected to the lower conductive structure, and wherein the at least one transistor structure is disposed in one of the first IC die or the second IC die.

2. The IC device of claim 1, wherein the lower conductive structure comprises a single lower conductive element contacting the at least one dielectric structure and contiguously spanning at least a portion of each of the plurality of pixel circuits in the plan view of the IC device.

3. The IC device of claim 2, wherein:
the at least one dielectric structure comprises a single dielectric element disposed on the single lower conductive element; and
a perimeter of the single lower conductive element completely surrounds a perimeter of the single dielectric element in a plan view of the IC device.

4. The IC device of claim 2, wherein:
the at least one dielectric structure comprises a plurality of dielectric elements disposed on the single lower conductive element; and
each of the plurality of upper conductive elements is disposed on a corresponding one of the plurality of dielectric elements.

5. The IC device of claim 1, wherein:
the lower conductive structure comprises:
a single lower conductive element contiguously spanning at least a portion of each of the plurality of pixel circuits in the plan view of the IC device; and
a plurality of lower conductive elements that are disposed on the single lower conductive element and laterally separated from each other in the plan view of the IC device;
the at least one dielectric structure comprises a plurality of dielectric elements;
each of the plurality of dielectric elements is disposed on a corresponding one of the plurality of lower conductive elements; and
each of the plurality of upper conductive elements is disposed on a corresponding one of the plurality of dielectric elements.

6. The IC device of claim 1, wherein:
the charge storage structure comprises a plurality of capacitor structures; and
each of the plurality of capacitor structures includes a corresponding one of the plurality of upper conductive elements, a portion of the at least one dielectric structure, and a portion of the lower conductive structure.

7. The IC device of claim 1, wherein the at least one transistor structure comprises a single transistor structure disposed in the first IC die laterally external to the plurality of pixel circuits in the plan view of the IC device.

8. The IC device of claim 1, wherein the at least one transistor structure comprises a single transistor structure disposed in the second IC die laterally external to the plurality of pixel circuits in the plan view of the IC device.

9. The IC device of claim 1, wherein the at least one transistor structure comprises a plurality of transistor structures, each of the plurality of transistor structures comprising a source-drain region connected to, and disposed under, a corresponding portion of the lower conductive structure in the second IC die.

10. The IC device of claim 1, wherein each pixel circuit of the plurality of pixel circuits comprises:
a floating diffusion region;
a first transistor structure coupling the photodetector of the pixel circuit to the floating diffusion region; and
a second transistor structure coupling a corresponding one of the plurality of upper conductive elements of the charge storage structure to the floating diffusion region.

11. An integrated circuit (IC) device, comprising:
a first IC die comprising a plurality of pixel circuits, each of the plurality of pixel circuits comprising a photodetector; and
a second IC die disposed under, and coupled to, the first IC die, the second IC die comprising a charge storage structure, the charge storage structure contiguously spanning at least a portion of each of the plurality of pixel circuits in a plan view of the IC device, the charge storage structure comprising a plurality of capacitor structures, each of the plurality of capacitor structures disposed under and coupled to a corresponding one of the plurality of pixel circuits, the plurality of capacitor structures comprising a single lower conductive structure contiguously spanning at least a portion of each of the plurality of capacitor structures in the plan view of the IC device.

12. The IC device of claim 11, wherein the charge storage structure further comprises:
at least one dielectric structure disposed on the lower conductive structure; and
a plurality of upper conductive elements disposed on the at least one dielectric structure, each of the plurality of upper conductive elements electrically connected to a corresponding one of the plurality of pixel circuits.

13. The IC device of claim 12, wherein the lower conductive structure extends into a peripheral area laterally beyond the plurality of pixel circuits in the plan view of the IC device.

14. The IC device of claim 13, wherein the first IC die comprises:
a transistor structure disposed in the peripheral area and comprising a source-drain region connected to the lower conductive structure.

15. The IC device of claim 13, wherein the second IC die comprises:
a transistor structure disposed in the peripheral area and comprising a source-drain region connected to the lower conductive structure.

16. The IC device of claim 12, wherein the second IC die comprises:
a plurality of transistor structures, each of the plurality of transistor structures comprising a source-drain region connected to, and disposed under, a corresponding portion of the lower conductive structure.

17. The IC device of claim 11, where the plurality of pixel circuits are arranged in a two-by-two configuration in the plan view of the IC device.

18. A method, comprising:
forming a first dielectric structure on a substrate for an IC die;
forming a first conductive layer on the first dielectric structure;
forming a dielectric layer on the first conductive layer;
forming a second conductive layer on the dielectric layer;
removing at least one portion of the second conductive layer to form a plurality of upper conductive elements;
removing at least one portion of the dielectric layer lateral to the plurality of upper conductive elements to form at least one dielectric element disposed under the plurality of upper conductive elements;
removing at least one portion of the first conductive layer lateral to the plurality of upper conductive elements to form a single lower conductive element disposed under the at least one dielectric element and extending laterally into a peripheral area beyond a perimeter of each of the plurality of upper conductive elements;
forming a plurality of first conductive structures in a second dielectric structure disposed over the first dielectric structure, wherein each of the plurality of first conductive structures connects to a corresponding one of the plurality of upper conductive elements and extends to an upper side of the second dielectric structure; and
bonding the upper side of the second dielectric structure to an upper side of another IC die comprising a plurality of pixel circuits to electrically couple each of the plurality of upper conductive elements to a corresponding one of the plurality of pixel circuits.

19. The method of claim 18, further comprising:
forming a second conductive structure in the first dielectric structure in the peripheral area, the second conductive structure connecting a source-drain region of the substrate to the single lower conductive element.

20. The method of claim 18, further comprising:
forming a second conductive structure in the second dielectric structure in the peripheral area, the second conductive structure connecting to the single lower conductive element and extending to the upper side of the second dielectric structure.
